(19) United States
(12) Patent Application Publication
(10) Pub. No.: US 2006/0131603 A1
(43) Pub. Date: Jun. 22, 2006

(54) Semiconductor laser diode

(75) Inventor: Soo-haeng Cho, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG ELECTRO-MECHANICS CO., LTD., Suwon-si (KR)

(21) Appl. No.: 11/220,620

(22) Filed: Sep. 8, 2005

(30) Foreign Application Priority Data
Dec. 17, 2004 (KR) 10-2004-0108030

(51) Int. Cl. H01L 33/00

(52) U.S. Cl. 257/103

(57) ABSTRACT

A semiconductor laser diode is provided. The semiconductor laser diode includes a substrate; a lower clad layer on a substrate; an active layer on the lower clad layer; and an upper clad layer on the active layer and having a ridge that protrudes in a vertical direction. In the upper clad layer, impurity layers are formed by diffusing impurities at both sides of the ridge to suppress high-order traverse-mode lasing. The impurities are Ga-ions free vacancies or Zn ions.

### CROSS-REFERENCE TO RELATED PATENT APPLICATION

This application claims the priority of Korean Patent Application No. 10-2004-0108030, filed on Dec. 17, 2004, in the Korean Intellectual Property Office, the disclosure of which is incorporated herein in its entirety by reference.

### BACKGROUND OF THE DISCLOSURE

1. Field of the Invention

The present disclosure relates to a semiconductor laser diode, and more particularly, to a semiconductor laser diode, in which impurity regions are disposed on both sides of a ridge to suppress lasing in high-order traverse modes.

2. Description of the Related Art

In general, a semiconductor laser diode is widely used to transmit data or write and read data at high speed in the field of communications or optical disk players because it is comparatively small-sized and requires a smaller threshold current for lasing than other typical laser devices.

A laser diode for an optical disk player requires not only high optical efficiency and a long lifetime, but also a stable single transverse mode laser operating property (i.e., a kink free property). In particular, since a laser diode for a digital versatile disk (DVD) should operate at high speed, it requires a high power output characteristic.

FIG. 1 is a cross sectional view of a conventional semiconductor laser diode.

Referring to FIG. 1, the conventional semiconductor laser diode includes an n-clad layer 20, a resonant layer 30, and a p-clad layer 40, which are sequentially stacked on a substrate 10. The resonant layer 30 includes an n-waveguide layer 32, an active layer 34, and a p-waveguide layer 36. An etch stop layer 42 for forming a ridge 44 may be interposed in the p-clad layer 40. A p-contact layer 50 is disposed on the ridge 44, and a current blocking layer 60 covers a top surface of the p-clad layer 40 and an edge of the p-contact layer 50. A p-type electrode 70 is formed to contact a portion of the p-contact layer 50, which is exposed by the current blocking layer 60. Also, an n-type electrode 80 is disposed on a bottom surface of the substrate 10.

FIGS. 2A and 2B are schematic cross-sectional views for explaining lasing modes of the semiconductor laser diode shown in FIG. 1, and FIG. 3 is a graph showing an optical output characteristic of a conventional semiconductor laser diode.

Referring to FIG. 2A, in a fundamental mode of the semiconductor laser diode having the ridge 44, a peak of the optical field is formed at a central region under the ridge 44 to generate laser-beams. In such a fundamental mode, the power of emitted laser beams is constantly increased at a threshold current or higher.

Meanwhile, referring to FIG. 2B, in a first-order mode (a high-order mode) of the semiconductor laser diode, lasing areas are mostly formed at both sides of the ridge 44, and peaks of optical field exist at both sides of the ridge 44. When laser beams are emitted in the first-order mode, since optical power in the fundamental mode is partially converted into optical power in the high-order mode, output power is not changed linearly at a predetermined current as shown in FIG. 3 (this is generally termed a “kink level”). When the kink level is below a predetermined optical power (e.g., 250 mW), a laser diode for a high-speed DVD cannot normally operate.

To overcome this drawback, it is necessary to suppress lasing in high-order traverse modes including a first-order mode.

### SUMMARY OF THE DISCLOSURE

The present invention may provide a semiconductor laser diode, in which impurity regions for increasing loss in high-order traverse-mode regions are disposed on both sides of a ridge to suppress lasing in high-order traverse modes.

According to an aspect of the present invention, there may be provided a semiconductor laser diode including a substrate; a lower clad layer on a substrate; an active layer on the lower clad layer; and an upper clad layer on the active layer and having a ridge that protrudes in a vertical direction. Herein, the upper clad layer includes impurity layers, which are formed by diffusing impurities at both sides of the ridge to suppress high-order traverse-mode lasing.

In one embodiment, the impurities may be vacancies formed in the upper clad layer.

The vacancies may be formed by a depletion of Ga ions in the upper clad layer.

In another embodiment, the impurities may be Zn ions doped into the upper clad layer.

The impurity layers may be spaced at least 0.5 μm apart from both lateral surfaces of the ridge.

The semiconductor laser diode may further include an etch stop layer formed in the upper clad layer under the ridge.

The semiconductor laser diode may be formed of one of a GaAs-based semiconductor compound and a GaP-based semiconductor compound.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a conventional semiconductor laser diode;

FIGS. 2A and 2B are schematic cross-sectional views for illustrating lasing modes of the semiconductor laser diode shown in FIG. 1;

FIG. 3 is a graph showing an optical output characteristic of a conventional semiconductor laser diode;

FIG. 4 is a cross-sectional view of a semiconductor laser diode according to an exemplary embodiment of the present invention;

FIG. 5 is a diagram illustrating a process of forming impurity regions according to the present invention;

FIG. 6 is a graph of photoluminescence (PL) peak versus the annealing temperature to confirm a difference in energy bandgap between a region where a vacancy is formed and a region where no vacancy is formed; and

FIGS. 7A and 7B are graphs of PL peak versus wavelength of a quantum well (QW) to confirm a difference between a Zn undoped region and a Zn doped region in a laser diode formed of AlGaInP.

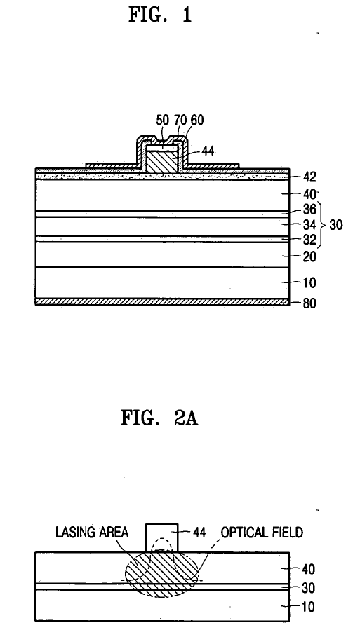

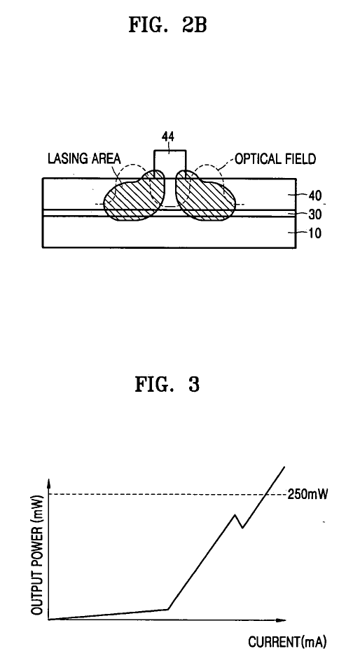

### DETAILED DESCRIPTION OF EXEMPLARY EMBODIMENTS

The present invention will now be described more fully with reference to the accompanying drawings, in which an exemplary embodiment of the invention is shown. A semiconductor laser diode according to the invention should not be construed as being limited to a stacked structure of the embodiment set forth herein and may be embodied as different structures formed of other III-V group compound semiconductor materials.

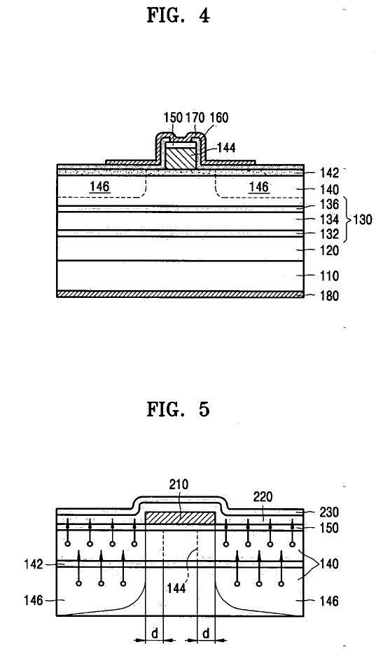

FIG. 4 is a cross-sectional view of a semiconductor laser diode according to an exemplary embodiment of the present invention.

Referring to FIG. 4, the semiconductor laser diode according to the exemplary embodiment of the present invention includes an n-clad layer 120, a resonant layer 130, and a p-clad layer 140, which are sequentially stacked on a substrate 110. The resonant layer 130 includes an n-waveguide layer 132, an active layer 134, and a p-waveguide layer 136. An etch stop layer 142 for forming a ridge 144 may be interposed in the p-clad layer 140. A p-contact layer 150 is disposed on the ridge 144, and a current blocking layer 160 covers a top surface of the p-clad layer 140 and an edge of the p-contact layer 150. A p-type electrode 170 is formed to contact a portion of the p-contact layer 150, which is exposed by the current blocking layer 160. Also, an n-type electrode 180 is disposed on a bottom surface of the substrate 110.

The substrate 110 may be formed of a p-GaAs or n-GaP conductive material.

The n-clad layer 120 may be formed of an n-(Al_{0.7}Ga_{0.3})_{0.5}In_{0.5}P compound semiconductor. In this case, the n-clad layer 120 may be obtained by epitaxially growing an AlGaInP-based compound semiconductor on the substrate 110 while varying the Al content.

The n-waveguide layer 132, the active layer 134, and the p-waveguide layer 136 are sequentially formed on a top surface of the n-clad layer 120. In this case, the n-waveguide 132 and the p-waveguide layer 136, which guide lasing, are formed of compound semiconductors having higher refractive indexes than those of the n- and p-clad layers 120 and 140. For example, the n-waveguide 132 and the p-waveguide layer 136 may be formed of an n-(Al_{0.53}Ga_{0.47})_{0.5}In_{0.5}P compound semiconductor and a p-(Al_{0.53}Ga_{0.47})_{0.5}In_{0.5}P compound semiconductor, respectively.

Also, the active layer 134, which causes lasing, is formed of a compound semiconductor having a higher refractive index than those of the n- and p-waveguide layers 132 and 136. For example, the active layer 134 may be formed of a Ga_{0.5}In_{0.5}P compound semiconductor. Here, the active layer 134 may have one of a multiple quantum well (MQW) structure and a single quantum well (SQW) structure.

The p-clad layer 140 disposed on a top surface of the p-waveguide layer 134 is formed of a compound semiconductor having the same refractive index as that of the n-clad layer 120. For example, the p-clad layer 140 may be formed of a p-(Al_{0.7}Ga_{0.3})_{0.5}In_{0.5}P compound semiconductor. Meanwhile, the etch stop layer 142, which is disposed in the p-clad layer 140, assists in forming the ridge 144 to a precisely desired height while the ridge 144 is being formed by etching an upper portion of the p-clad layer 140.

In the meantime, predetermined impurity regions 146 are formed in the p-clad layer 140 on both sides of the ridge 144. The impurity regions 146 include Ga-ions free vacancies or Zn ions as impurities. The impurity regions 146 induce scattering of an optical field region formed in a first-mode region and increase loss in the first-mode region, thus suppressing lasing. Preferably, the impurity regions 146 are spaced about 0.5 μm apart from both lateral surfaces of the ridge 144. When the ridge 144 has a width of about 1 to 2 μm, because fundamental-mode lasing happens in a region that reaches 0.5 μm from the both lateral surfaces of the ridge 144, the impurity regions 146 may be formed outside the region. The impurity regions 146 may be limited to the depth of regions 146 as illustrated with dotted lines in FIG. 4 or may be formed to a greater depth such that impurities diffuse into the underlying layers.

In the present embodiment, the semiconductor laser diode including the n- and p-clad layers 120 and 140 and the resonant layer 130 is formed of an AlGaInP compound, but the present invention is not limited thereto. That is, the semiconductor laser diode can be formed of other GaAs-based or GaP-based III-V group compound semiconductors.

FIG. 5 is a diagram illustrating an example of a process of forming impurity regions according to the present invention.

Referring to FIG. 5, a p-clad layer 140 and a p-contact layer 150 are sequentially formed on a resonant layer 130 using a known method. Thereafter, a diffusion control mask 210 is formed on the ridge forming portion 144 at a region that reaches 0.5 μm from both lateral surfaces of the ridge forming portion 144. The mask 210 may be formed of silicon nitride. In this case, an etch stop layer 142 may be formed in the p-clad layer 140. Subsequently, an absorption layer 220 is formed to cover the mask 210 on the p-clad layer 140 in order to generate impurities using a diffusion process. The absorption layer 220 may be formed of SiO₂ using a sputtering process. After that, a passivation layer 230 is formed on the absorption layer 220.

Thereafter, when the p-clad layer 140 is heated to a temperature of about 600 to 800° C., Ga ions diffuse from the p-clad layer 140 toward the absorption layer 220 so that Ga-ions free vacancies are formed in a portion of the p-clad layer 140, which is not covered by the mask 210. Typically, in order to control a diffusion region, bandgaps of quantum wells (QWs) of an impurity diffusion region (at both sides of the ridge forming portion 144) and an impurity non-diffusion region (corresponding to the ridge forming portion 144) are measured and compared with each other. Thus, as QWs in a region where a vacancy is formed are intermixed due to the diffusion, the bandgap of the QWs becomes greater and the wavelength of the QWs becomes shorter. Accordingly, it can be confirmed that vacancies are formed in regions that are not covered by the mask 210. After the diffusion process is finished, the diffusion control mask 210, the remaining absorption layer 220 and the passivation layer 230 are removed, and subsequent processes for fabricating a laser diode are performed.

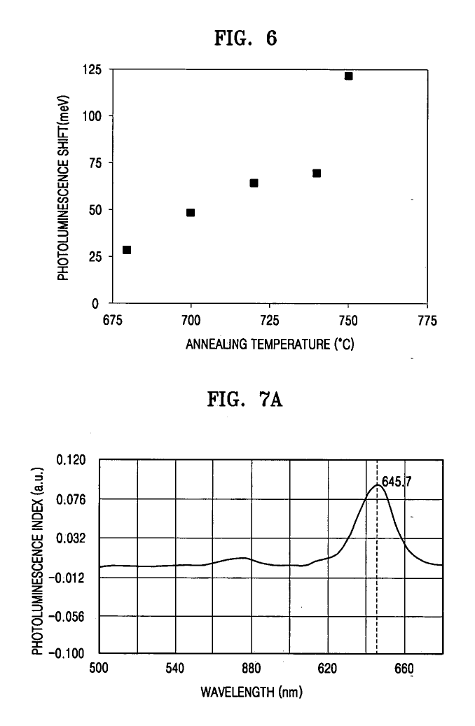

In order to confirm a difference in energy bandgap between a region where a vacancy is formed and a region where no vacancy is formed, a photoluminescence (PL) peak relative to an annealing temperature was measured, and results of the measurement was illustrated in FIG. 6. Referring to FIG. 6, the vacancy resulting from a raise in the annealing temperature of the p-clad layer 140 of the laser diode composed of AlGaInP can be observed from a difference of PL peak and PL peak shift.

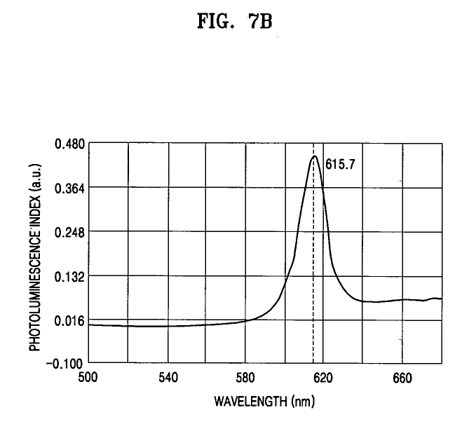

In the meantime, when a ZnO layer is formed in place of the SiO₂ absorption layer 220 in FIG. 6, Zn ions diffuse into a portion of the p-clad layer 140, which are not covered by the mask 210, thus forming impurities. FIGS. 7A and 7B are graphs of PL peak versus wavelength in QWs of a Zn undoped region and a Zn doped region in a laser diode composed of AlGaInP, respectively. In this case, the p-clad layer 140 was annealed at a temperature of about 510 ° C. for 30 minutes.

Referring to FIGS. 7A and 7B, PL reached a peak at a wavelength of 645.7 nm in the QW of the Zn undoped region, whereas PL reached a peak at a wavelength of 615.7 nm in the QW of the Zn doped region. A reduction in wavelength at which PL reaches a peak in a certain region indirectly shows that impurities diffuse into the region. In other words, impurity regions, in which Zn ions are doped or vacancies are formed from a scattering layer, and the scattering layer increases loss in high-order traverse-mode including a first-order mode. Thus, lasing can be suppressed in the high-order modes except a fundamental mode in which there are no or few portions that overlap impurity regions. As a result, a kink level caused by high-order lasing can be elevated to a desired high level.

As described above, in a semiconductor laser diode according to the present invention, impurity regions formed at both sides of a ridge can increase loss in a high-order traverse mode region so that lasing can be suppressed in high-order traverse modes. Hence, an optical power at which a kink level is generated can be elevated, thus resulting in an excellent semiconductor laser diode, in which the kink level is not generated in a predetermined optical output region.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor laser diode comprising:
a substrate;
a lower clad layer on a substrate;
an active layer on the lower clad layer; and
an upper clad layer on the active layer and having a ridge that protrudes in a vertical direction,
wherein the upper clad layer includes impurity layers, which are formed by diffusing impurities at both sides of the ridge to suppress high-order traverse-mode lasing.

2. The semiconductor laser diode of claim 1, wherein the impurities are vacancies formed in the upper clad layer.

3. The semiconductor laser diode of claim 2, wherein the vacancies are formed by a depletion of Ga ions in the upper clad layer.

4. The semiconductor laser diode of claim 1, wherein the impurities are Zn ions doped into the upper clad layer.

5. The semiconductor laser diode of claim 1, wherein the impurity layers are spaced at least 0.5 μm apart from both lateral surfaces of the ridge.

6. The semiconductor laser diode of claim 1, further comprising an etch stop layer formed in the upper clad layer under the ridge.

7. The semiconductor laser diode of claim 1, wherein the semiconductor laser diode is formed of a composition selected from the group consisting of a GaAs-based semiconductor compound and a GaP-based semiconductor compound.

8. The semiconductor laser diode of claim 7, further comprising a first electrode and a second electrode disposed on a top surface of the ridge and a bottom surface of the substrate, respectively.

9. The semiconductor laser diode of claim 7, wherein the active layer is formed of an AlGaInP-based compound semiconductor.
